(19) United States
(12) Patent Application Publication
(10) Pub. No.: US 2004/0222862 A1
(43) Pub. Date: Nov. 11, 2004

(54) Voltage-controlled oscillator

(76) Inventor: Jacques Majos, Le Versoud (FR)

Correspondence Address: Eric B. Meyertons, MEYERTONS, HOOD, KIVLIN, KOWERT & GOETZEL, P.C., P.O. BOX 398, AUSTIN, TX, 78767-0398, US

(21) Appl. No.: 10/806,073

(22) Filed: Mar. 22, 2004

(30) Foreign Application Priority Data
Mar. 28, 2003 (FR) 0303898

(51) Int. Cl. H03B 1/00

(52) U.S. Cl. 331/117 R

(57) ABSTRACT

A voltage-controlled oscillator includes an oscillating stage with two coupled CMOS inverters forming a quadrupole with two inputs and with two outputs, and two oscillating circuits placed respectively between the inputs and the outputs of the inverters and each having an inductor, the quadrupole being designed so that the outputs of the quadrupole are in phase. The inductors of the oscillating circuits are produced in MOS technology and are superposed one on top of the other.

### BACKGROUND OF THE INVENTION

1. Field of the Invention

The invention generally relates to a voltage-controlled oscillator produced in CMOS technology. More particularly, the invention generally relates to frequency synthesis based on the use of a voltage-controlled oscillator slaved to a reference frequency.

2. Description of the Relevant Art

One particularly advantageous application of such a voltage-controlled oscillator relates to the telecommunications field for the production of radio transmitters or receivers, for which it is necessary to generate precise frequencies in order to select a radio channel. More particularly, one particularly advantageous application of the invention is in the field of high frequencies of the order of 5 GHz, these frequencies being adopted in certain local radio networks for the carrier wave so as not to interfere with neighboring networks.

Assigned to each communication is a channel contained in this frequency band, having a width of approximately 20 MHz. It is therefore necessary to have, at reception, a local oscillator capable of generating precise frequencies in order to select a given channel. Such an oscillator which is intended to be incorporated in the receive terminals, must necessarily have a low production cost and a high level of integration.

It is for this reason that these oscillators are generally produced in CMOS technology. In this technology, the oscillators typically include, for example, two identical oscillating circuits each comprising an LC-type resonant circuit, each circuit being associated with an inverter including the combination of two transistors.

As will be understood, one of the major preoccupations of telecommunication terminal manufacturers relates to the miniaturization of the electronic components incorporated therein. This problem is more acute in the case of the inductors of the constituent oscillators of the resonant circuits, the silicon area used to produce an inductor being directly dependent on the inductance of the inductor and therefore on the oscillation frequency. It is therefore not possible to reduce the size of the oscillator without modifying the inductance of the inductor and therefore the frequency of the oscillator.

Thus, in MOS technology, the area of silicon needed to produce the transistors of the oscillator is negligible compared with the area of silicon needed to produce the inductors.

### SUMMARY OF THE INVENTION

In one embodiment, to alleviate the drawbacks of the oscillators of the prior art, a voltage-controlled oscillator with a higher degree of integration is described.

According to one embodiment, a voltage-controlled oscillator is therefore proposed, including an oscillating stage with two coupled CMOS inverters forming a quadrupole with two inputs and with two outputs, and two oscillating circuits placed respectively between the inputs and the outputs of the inverters and each having an inductor, the quadrupole being designed so that the outputs of the quadrupole are in phase.

According to a general feature of the oscillator, the inductors of the oscillating circuits are produced in MOS technology and are superposed one on top of the other.

The superposition of the two inductors consequently allows the area occupied by the oscillator to be reduced, possibly by a factor of up to 2.

According to another feature of the oscillator, the inductors of the oscillating circuits may be produced in the form of spirals implanted in respective metallization levels of an integrated circuit. Thus, for example, the inductors are in the form of spiraled capacitors formed respectively by metal implantation in the metallization levels that are isolated by a thin oxide film.

According to another feature of the oscillator, each inverter includes two oppositely biased MOS transistors placed in line, the input of the inverters being located on the gate of one of the transistors having a first bias and the output at the mid-point of the two transistors.

Furthermore, the input of each inverter is coupled to the gate of a transistor with a second bias of the other inverter, the second bias being opposite that of the first bias.

The oscillator furthermore includes an amplification stage including two oppositely biased MOS transistors placed in series, the gate of each MOS transistor being coupled to one of the outputs of the oscillating stage.

### BRIEF DESCRIPTION OF THE DRAWINGS

Other objects and advantages of the invention will become apparent upon reading the following detailed description and upon reference to the accompanying drawings in which:

FIG. 1 is a diagram illustrating the production of a voltage-controlled oscillator according to the invention;

FIG. 2 is a sectional view of an integrated circuit wafer illustrating the production of the inductors of an oscillator according to the invention; and

FIG. 3 is a top view of the wafer of FIG. 2.

While the invention is susceptible to various modifications and alternative forms, specific embodiments thereof are shown by way of example in the drawings and will herein be described in detail. It should be understood, however, that the drawing and detailed description thereto are not intended to limit the invention to the particular form disclosed, but on the contrary, the intention is to cover all modifications, equivalents and alternatives falling within the spirit and scope of the present invention as defined by the appended claims.

### DETAILED DESCRIPTION OF THE PREFERRED EMBODIMENTS

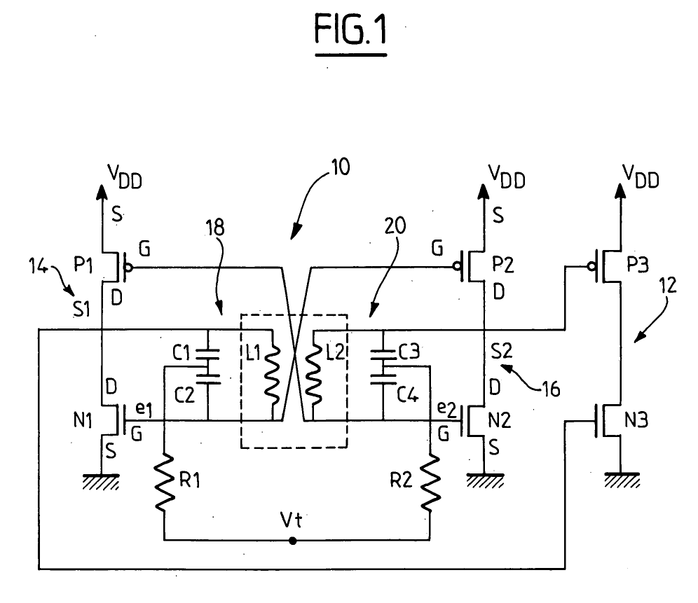

FIG. 1 shows the electronic circuit of a voltage-controlled oscillator according to one embodiment. As may be seen in this FIG. 1, the oscillator includes an oscillating stage 10 associated with an amplifier stage 12 of the “push-pull” type. The oscillating stage 10 includes a quadrupole with two inputs e1 and e2 and with two outputs s1 and s2.

In particular, the oscillating stage 10 has a structure including two coupled inverters 14 and 16 that are produced in CMOS technology. Each inverter 14 and 16 includes two oppositely biased MOS transistors, respectively N1, P1, N2, and P2, which are placed in series. In other words, one of the inverters, namely the inverter denoted by the general numerical reference 14, includes a first MOS transistor N1 of an n-type and a second MOS transistor P1 of a p-type that are coupled in such a way that the source S of the MOS transistor N1 is earthed, the source S of the second transistor P1 is connected to a voltage supply V_{DD} and the drain D of the first transistor N1 is connected to the drain of the second transistor P1. The other inverter 16 is wired in a symmetrical manner.

FIG. 1 shows that the two inputs e1 and e2 of quadrupole 10 are formed by the gates G of the first transistors N1 and N2 of the two inverters 14 and 16, whereas the outputs s1 and s2 are formed by the drains D of the two transistors N1, P1 on the one hand, and N2, P2 on the other. These outputs s1 and s2 are coupled to the amplification stage 12.

Amplification stage 12 is formed by the combination of two oppositely biased MOS transistors N3 and P3 placed in series, the respective gates of which receive the signals from the outputs s1 and s2 of the two inverters 14 and 16. This amplification stage forms a conventional push-pull amplifier. It will therefore not be described further below.

Finally, the oscillating stage 10 is completed by means of two oscillating or resonant circuits 18 and 20, placed in parallel between the inputs e1, e2 and the two outputs si, s2 of the two inverters 14 and 16, respectively. As may be seen in FIG. 1, these two oscillating circuits 18 and 20 are frequency-controlled by a tuning voltage Vt through two resistors R1 and R2. Each oscillating circuit 18 and 20 is formed by an inductor L1, L2 and, in parallel with it, a capacitor formed by two series-coupled capacitors C1, C2 and C3, C4, the mid-point of which is controlled by the tuning voltage Vt.

These oscillating circuits 18 and 20 thus each constitute an inductor coupled in parallel with a capacitor, which capacitor is successively charged and then discharged through the inductor L1, L2, thus creating oscillations whose frequency depends on the capacitance of the capacitors C1, C2 and C3, C4 and on the inductance of the inductors L1 and L2.

As indicated above, producing the inductors in CMOS technology has major drawbacks in terms of the area of silicon needed to produce these components.

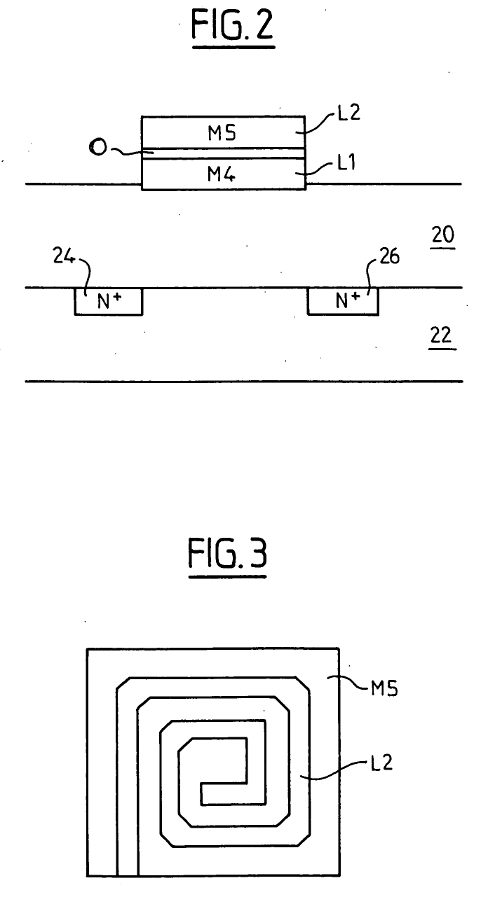

According to one embodiment, as shown in FIG. 2, inductors L1 and L2 are formed in two metallization levels M4 and M5 isolated by a thin oxide film O and are superposed one on top of the other, thereby considerably reducing the area of silicon needed to produce these inductors. This is because, as FIG. 2 shows, these inductors, L1 and L2, are formed in the two last metallization levels, M4 and M5, on a silicon oxide film 20 which is itself deposited on a p-type substrate 22, n⁺-doped wells 24 and 26 being provided, in the substrate 20, on either side of the inductors so as to limit losses in the latter.

As may be seen in FIG. 3, in which only the upper metallization level M5 has been shown, the inductors are produced by metal implantation in the form of spirals and they constitute, jointly, a spiraled capacitor. The two inductors are therefore coupled, forming a capacitor. However, the presence of such a capacitor is not a problem since the potential difference between the inductors L1 and L2 is zero.

Preferably, as may be seen in FIG. 2, use is made inter alia of the final metallization level M5, which has a greater thickness, in order to produce the inductors. It should be noted that the mutual inductance between the two inductors allows the properties of the oscillator to be modified. This is because, in a configuration with stacked inductors, if each inductor has an inductance value L, because of the coupling between these two inductors, each inductance value L′ then becomes:

L′=L(1+k)

where k denotes the coefficient of mutual inductance of the two inductors.

It will be consequently understood that, using such a structure of stacked inductors for the implantation of the inductors L1 and L2, if the coefficient k of mutual inductance is close to 1, the inductance value of each inductor is doubled, thereby making it possible to half the diameter of each inductor.

Finally, it should be noted, that according to one feature of the arrangement of the two inverters 14 and 16, from the standpoint of wiring these inverters, the latter are not formed since the gates of the transistors N1 and P1 on the one hand, and N2 and P2 on the other, are not interconnected to one and the same point. However, the quadrupole 10, the inputs and the outputs of which correspond to the inputs e1, e2 and to the outputs s1, s2 of the inverters, has a maximum gain when the inputs e1 and e2 are in phase. In other words, when the quadrupole 10 has reached its nominal point of operation defined by the maximum gain, the inputs e1 and e2 are in phase and, as a result, the inverters 14 and 16 are functionally closed. It should also be noted that, in this case, the outputs s1 and s2 are also in phase, and this allows the amplification stage 12 to be fed directly.

Further modifications and alternative embodiments of various aspects of the invention may be apparent to those skilled in the art in view of this description. Accordingly, this description is to be construed as illustrative only and is for the purpose of teaching those skilled in the art the general manner of carrying out the invention. It is to be understood that the forms of the invention shown and described herein are to be taken as the presently preferred embodiments. Elements and materials may be substituted for those illustrated and described herein, parts and processes may be reversed, and certain features of the invention may be utilized independently, all as would be apparent to one skilled in the art after having the benefit of this description to the invention. Changes may be made in the elements described herein without departing from the spirit and scope of the invention as described in the following claims. In addition, it is to be understood that features described herein independently may, in certain embodiments, be combined.

What is claimed is:

1. A voltage-controlled oscillator, comprising an oscillating stage with two coupled CMOS inverters forming a quadrupole with two inputs and with two outputs, and two oscillating circuits placed respectively between the inputs and the outputs of the inverters and each oscillating circuit comprising an inductor, the quadrupole being configured such that the outputs of the quadrupole are in phase, wherein the inductors of the oscillating circuits are produced in MOS technology and are superposed one on top of the other.

2. The oscillator according to claim 1, wherein the inductors of the oscillating circuits are produced in the form of spirals implanted in respective metallization levels of an integrated circuit.

3. The oscillator according to claim 2, wherein the inductors are in the form of spiraled capacitors formed respectively by metal implantation in the metallization levels that are isolated by a thin oxide film.

4. The oscillator according to claim 1, wherein each inverter comprises two oppositely biased MOS transistors placed in line, the input of the inverters being located on the gate of one of the transistors having a first bias and the output at the mid-point of the two transistors.

5. The oscillator according to claim 4, wherein the input of each inverter is coupled to the gate of a transistor with a second bias of the other inverter, the said second bias being opposite that of the said first bias.

6. The oscillator according to claim 1, further comprising an amplification stage comprising two oppositely biased MOS transistors placed in series, the gate of each MOS transistor being coupled to one of the outputs of the oscillating stage.
